(19) United States
(12) Patent Application Publication
(10) Pub. No.: US 2025/0283914 A1
(43) Pub. Date: Sep. 11, 2025

(54) PROBE CARD DEVICE HAVING HEAT-DISSIPATION CONFIGURATION AND GUIDE BOARD MODULE THEREOF

(71) Applicant: CHUNGHWA PRECISION TEST TECH. CO., LTD., Taoyuan City (TW)

(72) Inventors: YU-JU LU, Taoyuan City (TW); HAO-YEN CHENG, Taoyuan City (TW); Rong-Yang Lai, Taoyuan City (TW); WEI-JHIH SU, Taichung City (TW)

(21) Appl. No.: 19/007,566

(22) Filed: Jan. 2, 2025

(30) Foreign Application Priority Data
Mar. 8, 2024 (TW) 113108513

(51) Int. Cl. G01R 1/073; H05K 7/20

(52) U.S. Cl. CPC G01R 1/07342; H05K 7/20509

(57) ABSTRACT

A guide board module of a probe card device includes two first guide boards, a first spacing sheet sandwiched between the two first guide boards, and a first heat-dissipation unit. Each of the two first guide boards has two first board surfaces respectively arranged on two opposite sides thereof and a plurality of first thru-holes penetrating therethrough. The first heat-dissipation unit includes two first covering layers and a first thermal conductor. The first covering layers are respectively formed on the two first board surfaces of one of the two first guide boards. A sum of areas of the two first covering layers is at least 50% of a sum of areas of the two first board surfaces. The first thermal conductor is connected in-between the two first covering layers and is formed in one of the first thru-holes of the corresponding first guide board.

### CROSS-REFERENCE TO RELATED PATENT APPLICATION

This application claims the benefit of priority to Taiwan Patent Application No. 113108513, filed on Mar. 8, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a probe card device, and more particularly to a probe card device having a heat-dissipation configuration and a guide board module thereof.

### BACKGROUND OF THE DISCLOSURE

When a conventional probe card device is used, a thermal energy generated from probes can only be dissipated through a structural design of the probes, such that one or more of the probes provided for generating (or loading) a larger amount of thermal energy may be damaged or burnt out.

### SUMMARY OF THE DISCLOSURE

In response to the above-referenced technical inadequacies, the present disclosure provides a probe card device having a heat-dissipation configuration and a guide board module thereof for effectively improving on the issues associated with conventional probe card devices.

In order to solve the above-mentioned problems, one of the technical aspects adopted by the present disclosure is to provide a probe card device having a heat-dissipation configuration, which includes a first guide board module, a second guide board module, and a plurality of conductive probes. The first guide board module includes two first guide boards, a first spacing sheet, and a first heat-dissipation unit. Each of the two first guide boards has two first board surfaces respectively arranged on two opposite sides thereof and a plurality of first thru-holes that penetrate through the two first board surfaces. The first spacing sheet is sandwiched between the two first guide boards along a thickness direction. The first heat-dissipation unit includes two first covering layers and at least one first thermal conductor. The two first covering layers respectively cover the two first board surfaces of one of the two first guide boards. The at least one first thermal conductor is connected in-between the two first covering layers and is formed in at least one of the first thru-holes of the one of the two first guide boards. The second guide board module is spaced apart from the first guide board module along the thickness direction, and includes two second guide boards, a second spacing sheet, and a second heat-dissipation unit. Each of the two second guide boards has two second board surfaces respectively arranged on two opposite sides thereof and a plurality of second thru-holes that penetrate through the two second board surfaces. The second spacing sheet is sandwiched between the two second guide boards along the thickness direction. The second heat-dissipation unit includes two second covering layers and at least one second thermal conductor. The two second covering layers respectively cover the two second board surfaces of one of the two second guide boards. The at least one second thermal conductor is connected in-between the two second covering layers and is formed in at least one of the second thru-holes of the one of the two second guide boards. The conductive probes are assembled to the first guide board module and the second guide board module. The conductive probes respectively pass through the first thru-holes of each of the two first guide boards and respectively pass through the second thru-holes of each of the two second guide boards. Moreover, a total sum of areas of the two first covering layers and areas of the two second covering layers is at least 50% of a total sum of areas of the two corresponding first board surfaces and areas of the two corresponding second board surfaces, and at least one of the conductive probes abuts against the at least one first thermal conductor and the at least one second thermal conductor, thereby enabling the first heat-dissipation unit and the second heat-dissipation unit to transmit and dissipate a thermal energy generated from the at least one of the conductive probes.

In order to solve the above-mentioned problems, another one of the technical aspects adopted by the present disclosure is to provide a guide board module of a probe card device having a heat-dissipation configuration. The guide board module includes two first guide boards, a first spacing sheet, and a first heat-dissipation unit. Each of the two first guide boards has two first board surfaces respectively arranged on two opposite sides thereof and a plurality of first thru-holes that penetrate through the two first board surfaces. The first spacing sheet is sandwiched between the two first guide boards along a thickness direction. The first heat-dissipation unit includes two first covering layers and at least one first thermal conductor. The two first covering layers respectively cover the two first board surfaces of one of the two first guide boards, and a sum of areas of the two first covering layers is at least 50% of a sum of areas of the two corresponding first board surfaces. The at least one first thermal conductor is connected in-between the two first covering layers and is formed in at least one of the first thru-holes of the one of the two first guide boards.

Therefore, the first guide board module and the second guide board module of the probe card device in the present disclosure are provided with the first heat-dissipation unit and the second heat-dissipation unit, respectively, such that the heat-dissipation area of at least one of the conductive probes (e.g., the conductive probe provided for generating a larger thermal energy) can be increased exponentially through the two first covering layers and the two second covering layers, thereby effectively preventing the at least one of the conductive probes from being burnt and damaged.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a probe head of a probe card device having a heat-dissipation configuration according to a first embodiment of the present disclosure;

FIG. 2 is a schematic cross-sectional view taken along line II-II of FIG. 1;

FIG. 3 is a schematic perspective view showing a first guide board module and a second guide board module of FIG. 1;

FIG. 4 is a schematic exploded view of the first guide board module of FIG. 3;

FIG. 5 is a schematic perspective view showing the first guide board module and the second guide board module of FIG. 1 in another configuration;

FIG. 6 is a schematic perspective view of the probe head of the probe card device according to a second embodiment of the present disclosure;

FIG. 7 is a schematic perspective view showing the first guide board module and the second guide board module of FIG. 6;

FIG. 8 is a schematic perspective view of the probe head of the probe card device according to a third embodiment of the present disclosure;

FIG. 9 is a schematic cross-sectional view taken along line IX-IX of FIG. 8; and

FIG. 10 is a schematic perspective view showing the first guide board module, the second guide board module, and an electronic component of FIG. 8.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

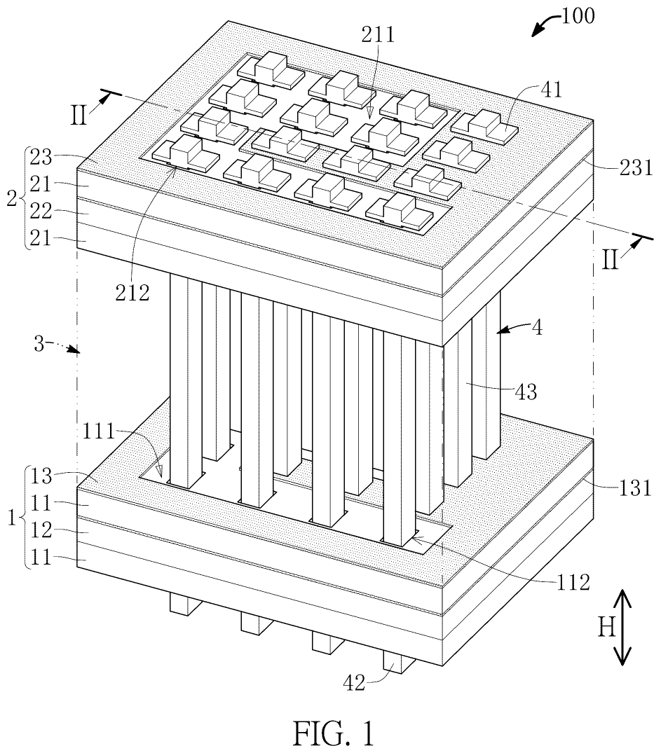

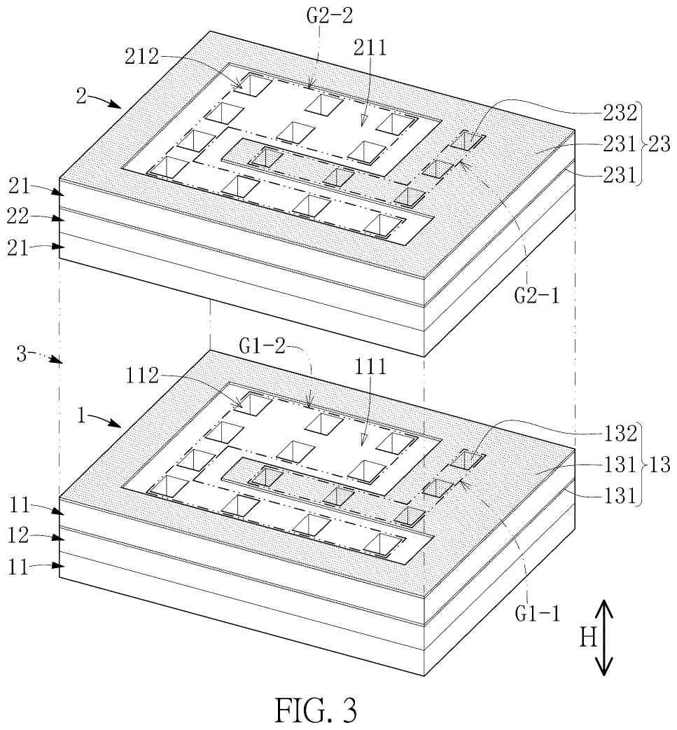

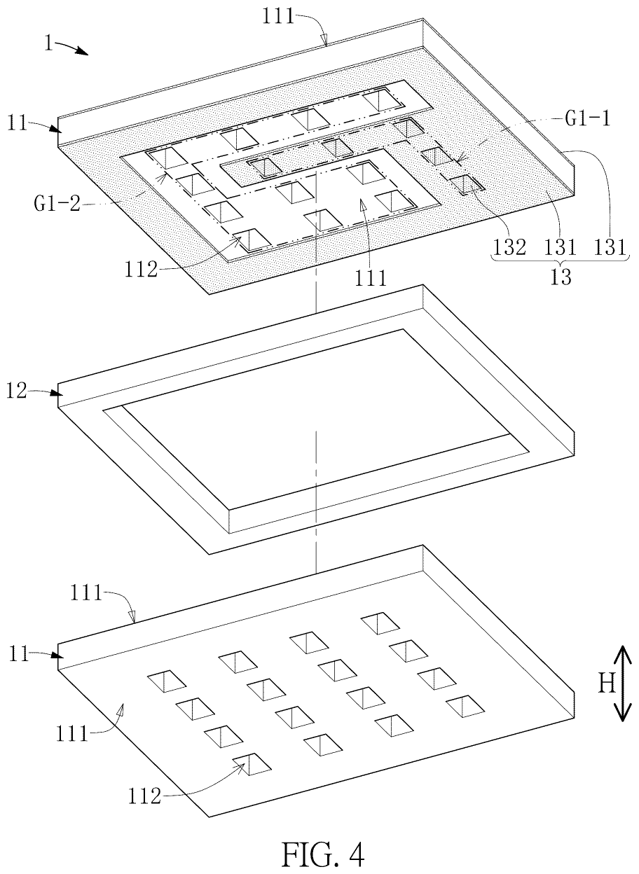

Referring to FIG. 1 to FIG. 5, a first embodiment of the present disclosure is provided. The present embodiment provides a probe card device 1000 having a heat-dissipation configuration, which includes a probe head 100 and a circuit board 200 (e.g., a space transformer) that is fixed to one side of the probe head 100. Moreover, another side of the probe head 100 is configured to detachably abut against a device under test (DUT) M for testing the DUT M.

In order to clearly describe the present embodiment, the drawings only depict a partial structure of the probe card device 1000 for clearly showing structure and connection relationship of each component of the probe card device 1000, but the present disclosure is not limited by the drawings. The following description describes the structure and connection relationship of each component of the probe card device 1000.

As shown in FIG. 1 to FIG. 4, the probe head 100 includes a first guide board module 1, a second guide board module 2 spaced apart from the first guide board module 1 along a thickness direction H, a spacer 3 sandwiched between the first guide board module 1 and the second guide board module 2, and a plurality of conductive probes 4 that are assembled to the first guide board module 1 and the second guide board module 2. The circuit board 200 is arranged adjacent to the second guide board module 2. That is to say, the second guide board module 2 is located between the circuit board 200 and the first guide board module 1.

It should be noted that the spacer 3 can be a frame structure and is sandwiched between a peripheral portion of the first guide board module 1 and a peripheral portion of the second guide board module 2, but the present disclosure is not limited thereto. For example, in other embodiments of the present disclosure not shown in the drawings, the spacer 3 of the probe card device 1000 can be omitted or can be replaced by other components. In addition, the first guide board module 1 and the second guide board module 2 in the present embodiment are described in cooperation with the above components, but the present disclosure is not limited thereto. For example, in other embodiments of the present disclosure not shown in the drawings, any one of the first guide board module 1 and the second guide board module 2 can be renamed as a guide board module that is independently used (e.g., sold) or that is used in cooperation with other components.

In the present embodiment, the first guide board module 1 includes two first guide boards 11, a first spacing sheet 12 sandwiched between the two first guide boards 11 along the thickness direction H, and a heat-dissipation unit 13 that is formed on one of the two first guide boards 11. The first spacing sheet 12 is sandwiched between peripheral portions of the two first guide boards 11, and the one of the two first guide boards 11 provided with the first heat-dissipation unit 13 formed thereon is located closer to the second guide board module 2 than another one of the two first guide boards 11.

Moreover, as the two first guide boards 11 in the present embodiment are of substantially the same structure, the following description discloses the structure of just one of the two first guide boards 11 for the sake of brevity, but the present disclosure is not limited thereto. For example, in other embodiments of the present disclosure not shown in the drawings, the two first guide boards 11 can be of different structures; or, each of the two first guide boards 11 can be provided with the first heat-dissipation unit 13 formed thereon.

Specifically, the first guide board 11 is flat and has two first board surfaces 111 respectively arranged on two opposite sides thereof and a plurality of first thru-holes 112 that penetrate through the two first board surfaces 111 (or that penetrate therethrough). The first thru-holes 112 in the present embodiment preferably have a same size and are in a matrix arrangement, but the present disclosure is not limited thereto.

Moreover, the first heat-dissipation unit 13 is made of a material (e.g., copper) having a high thermal conductivity, and includes two first covering layers 131 and at least one first thermal conductor 132 that is connected in-between the two first covering layers 131. The two first covering layers 131 cover (or are connected to) the two first board surfaces 111 of the corresponding first guide board 11, respectively, and the at least one first thermal conductor 132 is formed in at least one of the first thru-holes 112 of the corresponding first guide board 11.

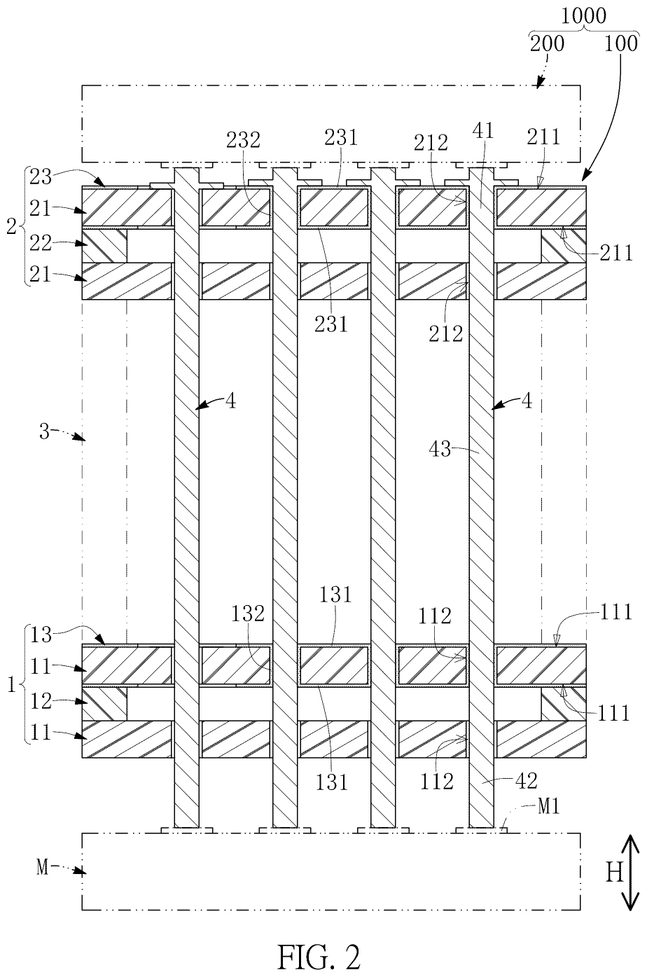

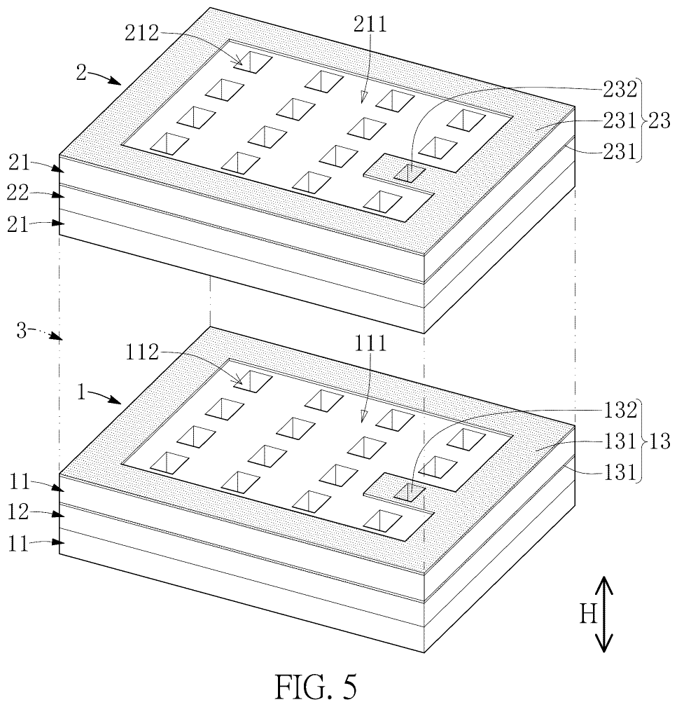

It should be noted that a quantity of the at least one first thermal conductor 132 of the first heat-dissipation unit 13 can be more than one (as shown in FIG. 2 to FIG. 4) or just one (as shown in FIG. 5). In the present embodiment, the first thermal conductor 132 is formed on an inner wall defining the first thru-hole 112 and has a tubular shape for allowing the conductive probe 4 to pass therethrough and to be connected thereto.

In the present embodiment, the second guide board module 2 includes two second guide boards 21, a second spacing sheet 22 sandwiched between the two second guide boards 21 along the thickness direction H, and a heat-dissipation unit 23 that is formed on one of the two second guide boards 21. The second spacing sheet 22 is sandwiched between peripheral portions of the two second guide boards 21, and the one of the two second guide boards 21 provided with the second heat-dissipation unit 23 formed thereon is located further away from the first guide board module 1 than another one of the two second guide boards 21.

Moreover, as the two second guide boards 21 in the present embodiment are of substantially the same structure, the following description discloses the structure of just one of the two second guide boards 21 for the sake of brevity, but the present disclosure is not limited thereto. For example, in other embodiments of the present disclosure not shown in the drawings, the two second guide boards 21 can be of different structures; or, each of the two second guide boards 21 can be provided with the second heat-dissipation unit 23 formed thereon.

Specifically, the second guide board 21 is flat and has two second board surfaces 211 respectively arranged on two opposite sides thereof and a plurality of second thru-holes 212 that penetrate through the two second board surfaces 211 (or that penetrate therethrough). The second thru-holes 212 in the present embodiment preferably have a same size and are in a matrix arrangement, and the second thru-holes 212 of each of the two second guide boards 21 respectively correspond in position to the first thru-holes 112 of each of the two first guide boards 11 along the thickness direction H, but the present disclosure is not limited thereto.

Moreover, the second heat-dissipation unit 23 is made of a material (e.g., copper) having a high thermal conductivity, and includes two second covering layers 231 and at least one second thermal conductor 232 that is connected in-between the two second covering layers 231. The two second covering layers 231 cover (or are connected to) the two second board surfaces 211 of the corresponding second guide board 21, respectively, and the at least one second thermal conductor 232 is formed in at least one of the second thru-holes 212 of the corresponding second guide board 21.

It should be noted that a quantity of the at least one second thermal conductor 232 of the second heat-dissipation unit 23 can be more than one (as shown in FIG. 2 to FIG. 4) or just one (as shown in FIG. 5). In the present embodiment, the second thermal conductor 232 is formed on an inner wall defining the second thru-hole 212 and has a tubular shape for allowing the conductive probe 4 to pass therethrough and to be connected thereto.

The conductive probes 4 in the present embodiment are of substantially the same structure. The conductive probes 4 respectively pass through the first thru-holes 112 of each of the two first guide boards 11 and respectively pass through the second thru-holes 212 of each of the two second guide boards 21. Accordingly, in practical use, each of the conductive probes 4 can be positioned and held through a staggered arrangement of the first guide board module 1 and the second guide board module 2.

Specifically, each of the conductive probes 4 has a fixing segment 41, a testing segment 42 being opposite to the fixing segment 41, and an extending segment 43 that connects the fixing segment 41 and the testing segment 42. In each of the conductive probes 4, the fixing segment 41 protrudes from the second guide board module 2 and is fixed to the circuit board 200, and the testing segment 42 protrudes from the first guide board module 1 and is configured to detachably abut against one of metal pads M1 of DUT M.

Moreover, in practical use (not shown in the drawings), the testing segment 42 of each of the conductive probes 4 can be positioned and held through a staggered arrangement of the two first guide boards 11, the fixing segment 41 of each of the conductive probes 4 can be positioned and held through a staggered arrangement of the two second guide boards 21, and the extending segment 43 of each of the conductive probes 4 is elastically deformed due to the staggered arrangement of the first guide board module 1 and the second guide board module 2, but the present disclosure is not limited thereto.

In the present embodiment, at least one of the conductive probes 4 abuts against one of the first thermal conductors 132 and one of the second thermal conductors 232, such that the first heat-dissipation unit 13 and the second heat-dissipation unit 23 can be configured to transmit and dissipate a thermal energy generated from the at least one of the conductive probes 4. In other words, any one of the conductive probes 4 passing through two of the first thru-holes 112 of the two first guide boards 11 not receiving the first thermal conductor 132 therein is not in contact with the first heat-dissipation unit 13, and any one of the conductive probes 4 passing through two of the second thru-holes 212 of the two second guide boards 21 not receiving the second thermal conductor 232 therein is not in contact with the second heat-dissipation unit 23.

Specifically, the first thru-holes 112 of each of the two first guide boards 11 in the present embodiment are defined into at least two first thru-hole groups G1-1, G1-2, the second thru-holes 212 of each of the two second guide boards 21 are defined into at least two second thru-hole groups G2-1, G2-2, and arrangements of the at least two first thru-hole groups G1-1, G1-2 are respectively identical to arrangements of the at least two second thru-hole groups G2-1, G2-2.

Each of the first thru-holes 112 of one of the at least two first thru-hole groups G1-1 is provided with one of the first thermal conductors 132 therein that abuts against one of the conductive probes 4. Each of the second thru-holes 212 of one of the at least two second thru-hole groups G2-1 is provided with one of the second thermal conductors 232 therein that abuts against one of the conductive probes 4. In other words, each of the first thermal conductors 132 and one of the second thermal conductors 232 substantially correspond in position to each other along the thickness direction H, and respectively abut against the testing segment 42 and the fixing segment 41 of one of the conductive probes 4.

Specifically, the first thermal conductors 132 are electrically coupled to each other through the two first covering layers 131, and the second thermal conductors 232 are electrically coupled to each other through the two second covering layers 231. Accordingly, the first heat-dissipation unit 13 can be provided to greatly increase a heat-dissipation area of the corresponding conductive probes 4 through the two first covering layers 131, and the second heat-dissipation unit 23 can be provided to greatly increase a heat-dissipation area of the corresponding conductive probes 4 through the two second covering layers 231.

Specifically, a total sum of areas of the two first covering layers 131 and areas of the two second covering layers 231 is at least 50% of a total sum of areas of the two corresponding first board surfaces 111 and areas of the two corresponding second board surfaces 211. In other words, a sum of the areas of the two first covering layers 131 is at least M % of a sum the areas of the two corresponding first board surfaces 111, and a sum of the areas of the two second covering layers 231 is at least N % of a sum of the areas of the two corresponding second board surfaces 211. Moreover, M and N are positive integers, and a sum of M and N is greater than or equal to 100. According to practical requirements, M and N in the present embodiment can be a same value (e.g., M=N=50) or can be different values (e.g., M=70 and N=40).

### Second Embodiment

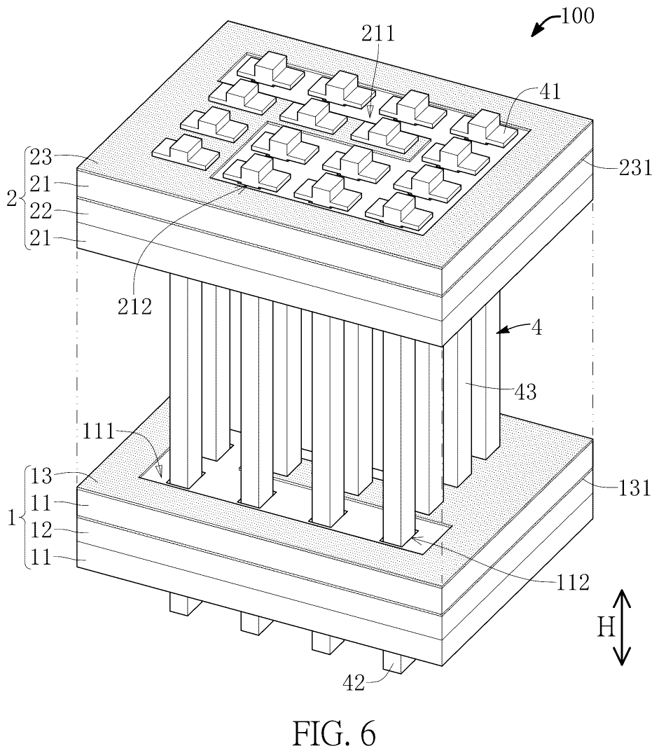

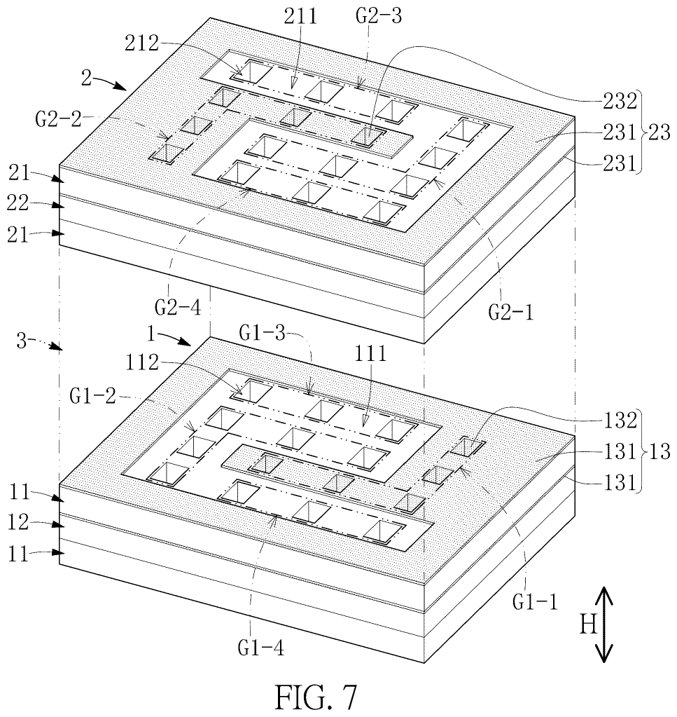

Referring to FIG. 6 and FIG. 7, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the first thru-holes 112 of each of the two first guide boards 11 are defined into four first thru-hole groups G1-1, G1-2, G1-3, G1-4, and the second thru-holes 212 of each of the two second guide boards 21 are defined into four second thru-hole groups G2-1, G2-2, G2-3, G2-4. Each of the first thru-holes 112 of one of the four first thru-hole groups G1-1 is provided with one of the first thermal conductors 132 therein that abuts against one of the conductive probes 4. Each of the second thru-holes 212 of one of the four second thru-hole groups G2-2 is provided with one of the second thermal conductors 232 therein that abuts against one of the conductive probes 4.

Specifically, each of the first thermal conductors 132 in the present embodiment does not correspond in position to any one of the second thermal conductors 232 along the thickness direction H, such that at least one of the first thermal conductors 132 and at least one of the second thermal conductors 232 respectively abut against at least two of the conductive probes 4 (e.g., the conductive probes 4 in contact with the first thermal conductors 132 are different from the conductive probes 4 in contact with the second thermal conductors 232).

### Third Embodiment

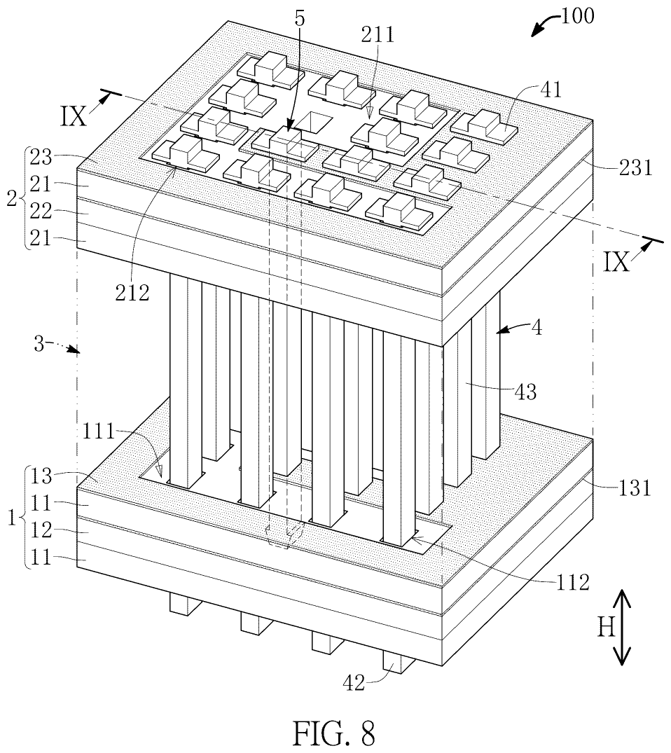

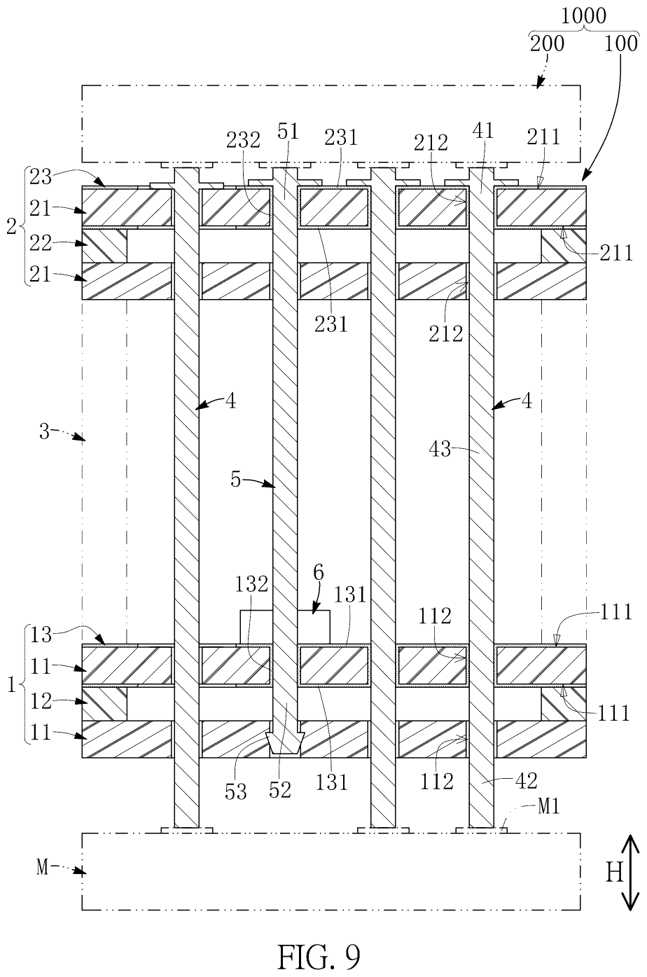

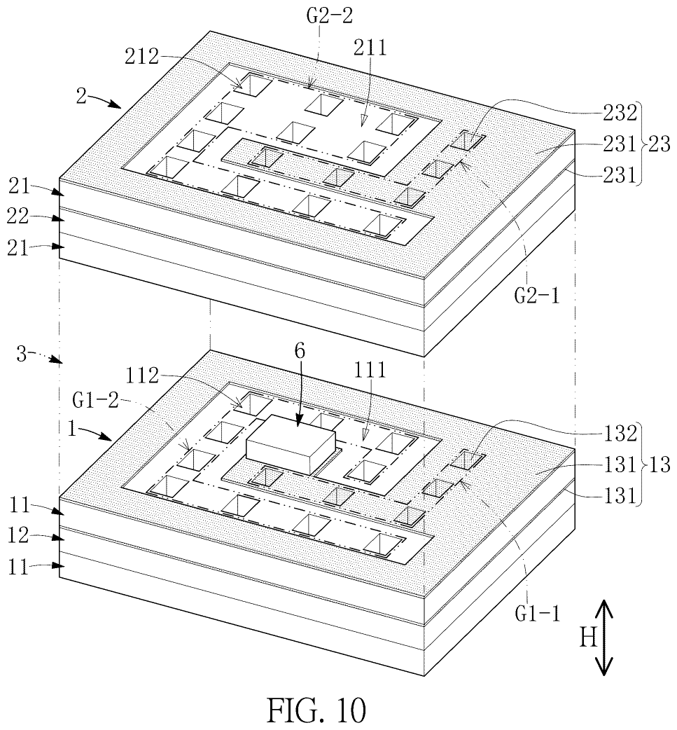

Referring to FIG. 8 to FIG. 10, a third embodiment of the present disclosure, which is similar to the first and second embodiments of the present disclosure, is provided. For the sake of brevity, descriptions of the same components in the first to third embodiments of the present disclosure will be omitted herein, and the following description only discloses different features among the first to third embodiments.

In the present embodiment, the probe card device 1000 further includes at least one auxiliary probe 5 and at least one electronic component 6 (e.g., a passive component) that is electrically coupled to the at least one auxiliary probe 5. The at least one auxiliary probe 5 is assembled to the first guide board module 1 and the second guide board module 2. Moreover, a quantity of the at least one auxiliary probe 5 and a quantity of the at least one electronic component 6 in the present embodiment can each be one, but the present disclosure is not limited thereto.

The auxiliary probe 5 has a connection segment 51 and an assembling segment 52. The connection segment 51 protrudes from the second guide board module 2 and is fixed to the circuit board 200, the assembling segment 52 is fixed in the first guide board module 1, and the assembling segment 52 is configured to face toward the DUT M and is not in contact with the DUT M. In the present embodiment, an outer diameter of the auxiliary probe 5 is substantially equal to that of any one of the conductive probes 4, and the assembling segment 52 of the auxiliary probe 5 has at least one thorn 53 that is arranged on a free end thereof and that is fixed to one of the first thru-holes 112 not receiving the first thermal conductor 132 of the first heat-dissipation unit 13.

Moreover, the electronic component 6 is assembled to the first guide board 11 provided with the first heat-dissipation unit 13 formed thereon, and is electrically coupled to the auxiliary probe 5 through the first heat-dissipation unit 13. In the present embodiment, the electronic component 6 and the first thru-holes 112 of the corresponding first guide board 11 are jointly in a matrix arrangement, a quantity of the conductive probes 4 is equal to a quantity of the metal pads M1 of the DUT M, and a portion of the DUT M facing toward the auxiliary probe 5 and the electronic component 6 along the thickness direction H does not have any metal pad M1 arranged thereon.

### BENEFICIAL EFFECTS OF THE EMBODIMENTS

In conclusion, the first guide board module and the second guide board module of the probe card device in the present disclosure are provided with the first heat-dissipation unit and the second heat-dissipation unit, respectively, such that the heat-dissipation area of at least one of the conductive probes (e.g., the conductive probe provided for generating a larger thermal energy) can be increased exponentially through the two first covering layers and the two second covering layers, thereby effectively preventing the at least one of the conductive probes from being burnt and damaged.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card device having a heat-dissipation configuration, comprising:
a first guide board module including:
two first guide boards each having two first board surfaces respectively arranged on two opposite sides thereof and a plurality of first thru-holes that penetrate through the two first board surfaces;
a first spacing sheet sandwiched between the two first guide boards along a thickness direction; and
a first heat-dissipation unit including:
two first covering layers respectively covering the two first board surfaces of one of the two first guide boards; and
at least one first thermal conductor connected in-between the two first covering layers and formed in at least one of the first thru-holes of the one of the two first guide boards;
a second guide board module being spaced apart from the first guide board module along the thickness direction and including:
two second guide boards each having two second board surfaces respectively arranged on two opposite sides thereof and a plurality of second thru-holes that penetrate through the two second board surfaces;
a second spacing sheet sandwiched between the two second guide boards along the thickness direction; and
a second heat-dissipation unit including:
two second covering layers respectively covering the two second board surfaces of one of the two second guide boards; and
at least one second thermal conductor connected in-between the two second covering layers and formed in at least one of the second thru-holes of the one of the two second guide boards; and
a plurality of conductive probes assembled to the first guide board module and the second guide board module, wherein the conductive probes respectively pass through the first thru-holes of each of the two first guide boards and respectively pass through the second thru-holes of each of the two second guide boards;
wherein a total sum of areas of the two first covering layers and areas of the two second covering layers is at least 50% of a total sum of areas of the two corresponding first board surfaces and areas of the two corresponding second board surfaces, and at least one of the conductive probes abuts against the at least one first thermal conductor and the at least one second thermal conductor, thereby enabling the first heat-dissipation unit and the second heat-dissipation unit to transmit and dissipate a thermal energy generated from the at least one of the conductive probes.

2. The probe card device according to claim 1, wherein the one of the two first guide boards provided with the first heat-dissipation unit formed thereon is located closer to the second guide board module than another one of the two first guide boards, and wherein the one of the two second guide boards provided with the second heat-dissipation unit formed thereon is located further away from the first guide board module than another one of the two second guide boards.

3. The probe card device according to claim 1, wherein the at least one first thermal conductor and the at least one second thermal conductor respectively abut against at least two of the conductive probes.

4. The probe card device according to claim 1, wherein any one of the conductive probes passing through two of the first thru-holes of the two first guide boards not receiving the at least one first thermal conductor therein is not in contact with the first heat-dissipation unit, and wherein any one of the conductive probes passing through two of the second thru-holes of the two second guide boards not receiving the at least one second thermal conductor therein is not in contact with the second heat-dissipation unit.

5. The probe card device according to claim 1, wherein a sum of the areas of the two first covering layers is at least M % of a sum the areas of the two corresponding first board surfaces, and a sum of the areas of the two second covering layers is at least N % of a sum of the areas of the two corresponding second board surfaces, and wherein M and N are positive integers, and a sum of M and N is greater than or equal to 100.

6. The probe card device according to claim 1, wherein the first thru-holes are defined into at least two first thru-hole groups, a quantity of the at least one first thermal conductor is more than one, and the first thermal conductors are electrically coupled to each other through the two first covering layers, and wherein each of the first thru-holes of one of the at least two first thru-hole groups is provided with one of the first thermal conductors therein that abuts against one of the conductive probes.

7. The probe card device according to claim 6, wherein the second thru-holes are defined into at least two second thru-hole groups, a quantity of the at least one second thermal conductor is more than one, and the second thermal conductors are electrically coupled to each other through the two second covering layers, wherein each of the second thru-holes of one of the at least two second thru-hole groups is provided with one of the second thermal conductors therein that abuts against one of the conductive probes, and wherein arrangements of the at least two first thru-hole groups are respectively identical to arrangements of the at least two second thru-hole groups.

8. The probe card device according to claim 1, further comprising:
a circuit board arranged adjacent to the second guide board module, wherein each of the conductive probes has a fixing segment and a testing segment that are respectively arranged on two opposite sides thereof, and wherein, in each of the conductive probes, the fixing segment protrudes from the second guide board module and is fixed to the circuit board, and the testing segment protrudes from the first guide board module and is configured to detachably abut against one of metal pads of a device under test (DUT); and
at least one auxiliary probe assembled to the first guide board module and the second guide board module, wherein the at least one auxiliary probe has a connection segment and an assembling segment, and wherein the connection segment protrudes from the second guide board module and is fixed to the circuit board, the assembling segment is fixed in the first guide board module, and the assembling segment is configured to face toward the DUT and is not in contact with the DUT.

9. A guide board module of a probe card device having a heat-dissipation configuration, comprising:
two first guide boards each having two first board surfaces respectively arranged on two opposite sides thereof and a plurality of first thru-holes that penetrate through the two first board surfaces;
a first spacing sheet sandwiched between the two first guide boards along a thickness direction; and
a first heat-dissipation unit including:
two first covering layers respectively covering the two first board surfaces of one of the two first guide boards, wherein a sum of areas of the two first covering layers is at least 50% of a sum of areas of the two corresponding first board surfaces; and
at least one first thermal conductor connected in-between the two first covering layers and formed in at least one of the first thru-holes of the one of the two first guide boards.

10. The guide board module according to claim 9, wherein the first thru-holes are defined into at least two first thru-hole groups, a quantity of the at least one first thermal conductor is more than one, and the first thermal conductors are electrically coupled to each other through the two first covering layers, and wherein each of the first thru-holes of one of the at least two first thru-hole groups is provided with one of the first thermal conductors therein.
